(19) United States
(12) Patent Application Publication
(10) Pub. No.: US 2009/0021134 A1
(43) Pub. Date: Jan. 22, 2009

(54) Organic EL Display Device

(76) Inventors: Noriharu MATSUDATE, Kujukuri (JP); Takeshi Ookawara, Mobara (JP); Masahiro Tanaka, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/176,749

(22) Filed: Jul. 21, 2008

(30) Foreign Application Priority Data
Jul. 20, 2007 (JP) 2007-188979

(51) Int. Cl. H01J 1/00

(52) U.S. Cl. 313/326

(57) ABSTRACT

The present invention provides an organic EL display device which exhibits a long lifetime. In an organic EL display device which includes pixel electrodes formed on a substrate, an insulation partition wall surrounding the pixel electrodes, an organic EL layer formed on the pixel electrodes, and a common electrode formed on the organic EL layer, the common electrode is formed of a transparent conductive film which is made of metal oxide, and an auxiliary electrode which is made of opaque metal containing Zn or Mg as a main component is arranged above the common electrode and at positions where the auxiliary electrode overlaps with the insulation partition wall. The auxiliary electrode may be arranged below the common electrode instead of being arranged above the common electrode.

### CLAIM OF PRIORITY

The present application claims priority from Japanese Application JP 2007-188979 filed on Jul. 20, 2007, the content of which is hereby incorporated by reference into this application.

### BACKGROUND OF THE INVENTION

1. Field of the Invention

The present invention relates to a technique for lowering resistance of a common electrode of a top-emission-type active matrix organic EL (Electroluminescent) display device (AM-OLED), and more particularly to an auxiliary electrode used in the display device.

2. Description of Related Art

A common electrode of a conventional active-matrix-type organic EL display device is formed of an opaque metal electrode made of aluminum or the like in a bottom-emission-type (BE-type) organic EL display device, and is formed of a transparent conductive film such as an IZO film or an ITO film in a top-emission-type (TE-type) organic EL display device.

The common electrode of the TE-type organic EL display device is formed of the transparent conductive film as described above and hence, the common electrode exhibits large resistance. Accordingly, a potential of the common electrode is not set to a fixed value in plane and hence, a voltage gradient is generated whereby the brightness irregularities are generated in plane. Accordingly, in the conventional TE-type active-matrix-type organic EL display device, as disclosed in JP-A-2007-73323 (patent document 1), sheet resistance is lowered by forming an auxiliary electrode made of Al on a pixel separation film which is formed around a pixel electrode.

### SUMMARY OF THE INVENTION

Although the conventional auxiliary electrode made of aluminum exhibits low resistance, a melting point of the conventional auxiliary electrode is extremely high. Accordingly, a vapor deposition mask is deformed due to the thermal expansion and hence, the accuracy of vapor deposition is lowered thus giving rise to a drawback that an organic EL display device having high accuracy and high brightness cannot be realized.

Further, a temperature of an element substrate per se of the organic EL display device is also elevated and hence, an organic EL layer which is already formed is damaged. Accordingly, a lifetime of the organic EL display device is shortened or light emitting efficiency of the organic EL display device is lowered.

It is an object of the present invention to provide an organic EL display device which exhibits high accuracy and a long lifetime.

Although a plurality of means is considered for overcoming the above-mentioned drawbacks, to explain typical examples, they are as follows.

First of all, in a TE-type active-matrix-type organic EL display device, a common electrode is constituted of a transparent conductive film made of metal oxide, an auxiliary electrode which is brought into contact with an upper surface or a lower surface of the common electrode and forms an opening at positions where the auxiliary electrode overlaps with the pixel electrode is provided, and the auxiliary electrode is made of a material which contains Zn or Mg as a main component.

Further, as another constitution of the TE-type active-matrix-type organic EL display device, a common electrode is constituted of a transparent conductive film made of metal oxide, an opaque auxiliary electrode which is brought into contact with an upper surface or a lower surface of the common electrode is provided at positions where the auxiliary electrode overlaps with gaps between pixel electrodes, and the auxiliary electrode is made of a material which contains Zn or Mg as a main component.

FIG. 4 shows an effect in forming the auxiliary electrode which is obtained as a result of adopting the auxiliary electrode having such constitution, and FIG. 5 shows a temperature and resistivity of the metal material under vapor pressure of 0.013 Pa. As shown in FIG. 5, the temperature under vapor pressure of 0.013 Pa of Zn or Mg is half of or less than half of the temperature of Al under vapor pressure of 0.013 Pa. By using Mg or Zn as the material of the auxiliary electrode, the increase of metal mask temperature ΔTm and the increase of substrate temperature ΔTs in forming the auxiliary electrode by way of a mask by vapor deposition can be restricted to 5° C. or less. The increase of temperature of the metal mask causes a distortion of the metal mask. According to the present invention, by restricting the increase of temperature of the metal mask, the misalignment ΔS of vapor deposition can be reduced to 5 μm or less. When Al is used as a material of the auxiliary electrode, due to the distortion of the metal mask, the misalignment of the vapor deposition is set to a value which falls with a range of 35±7 μm. To the contrary, when Mg or Zn is used as the material of the auxiliary electrode, compared to the misalignment of vapor deposition in a case that Al is used as the material of the auxiliary electrode, the misalignment of vapor deposition can be restricted to one-fifth or less. Further, as indicated by resistivities in a table shown in FIG. 5, resistivity of Zn or Mg is merely increased to a value approximately less than three times as large as resistivity of Al and hence, these materials can endure a practical use as a material of an electrode. As described above, when the auxiliary electrode can be manufactured by a vapor deposition mask having small distortion, it is possible to increase a light emitting area by narrowing a width of the pixel separation structure (bank) and hence, the organic EL display device having high brightness can be provided. Further, by restricting light emission brightness, it is possible to prolong a lifetime of the organic EL display device. Further, distortion of the vapor deposition mask can be restricted and hence, large-sizing of a screen of the organic EL display device to 17 inches, for example, can be also realized. Further, although the organic EL layer is fragile under high temperature, by adopting the low-temperature auxiliary electrode, the deterioration of the organic EL layer formed on the substrate can be restricted. Also thanks to such an action, the lifetime of the organic EL display device can be prolonged and, further, the organic EL display device can provide a high-quality image due to small deterioration of the organic EL layer.

Further, reflectivity of Zn or Mg is not high compared to reflectivity of Al which is conventionally used and hence, it is possible to provide an organic EL display device having high display quality. Specifically, color of Zn is black and hence, it is possible to remarkably enhance the contrast.

Further, when Zn is used as a material of the auxiliary electrode, on an edge of the auxiliary electrode in the width direction, a profile (a change of thickness) of a vapor-deposited film thickness becomes extremely small and hence, Zn is easily oxidized by oxygen which constitutes a transparent conductive film so as to form ZnO whereby the auxiliary electrode becomes transparent. As a result, influence attributed to some vapor deposition misalignment of the auxiliary electrode can be restricted to an extent that the influence cannot be recognized with naked eyes.

By lowering sheet resistance which is the combined resistance of the resistance of the common electrode and the resistance of the auxiliary electrode to 10 Ωcm or less, it is possible to eliminate brightness irregularities to an extent that the brightness irregularities cannot be recognized with naked eyes.

Further, the common electrode may preferably be made of oxide containing In, Zn or Sn by taking sheet resistance and transmissivity into consideration.

Further, the auxiliary electrode may preferably be formed by any one of resistance-heating vapor deposition, induction-heating vapor deposition, electronic-beam (EB) vapor deposition, and sputtering.

According to the present invention, it is possible to lower the temperature of the manufacturing processing and hence, the lifetime of the element of the organic EL display device can be prolonged.

### BRIEF DESCRIPTION OF THE DRAWINGS

FIG. 1 is a partial top plan view of an effective display region of an organic EL display device;

FIG. 2 is a partial cross-sectional view of the effective display region;

FIG. 3 is a partial cross-sectional view of the effective display region;

FIG. 4 is a view showing effects of an auxiliary electrode in forming the auxiliary electrode depending on a constitutional material of the auxiliary electrode; and

FIG. 5 is a view showing a temperature and resistivity of a metal material under vapor pressure of 0.013 Pa.

### DESCRIPTION OF THE PREFERRED EMBODIMENTS

Hereinafter, embodiments of the present invention are explained.

### Embodiment 1

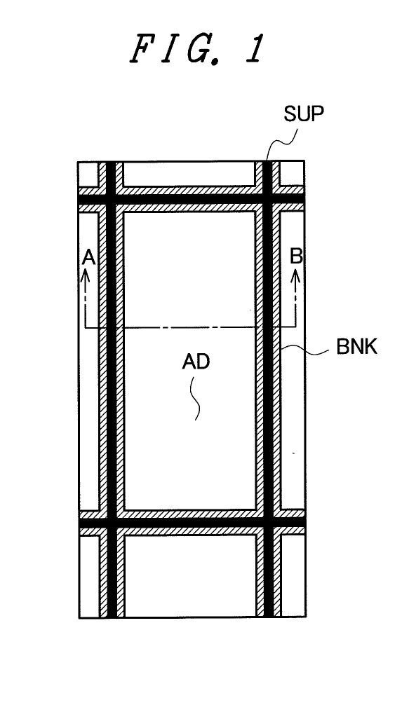

An organic EL display device of the present invention includes an EL substrate on which organic EL elements are formed and a sealing substrate which covers the organic EL elements. FIG. 1 is a partial top plan view of an effective display region of the EL substrate to which the present invention is applied. Anodes constituting pixel electrodes AD are arranged in a matrix array with a predetermined distance therebetween. Further, a pixel separation film BNK is formed in a grid pattern so as to expose the centers of respective pixel electrodes AD. An auxiliary electrode SUP is arranged at positions where the auxiliary electrode SUP and the pixel separation film BNK overlap with each other. Further, a cathode which constitutes a common electrode CD is formed on the whole display region below the auxiliary electrode SUP.

### (Layer Structure)

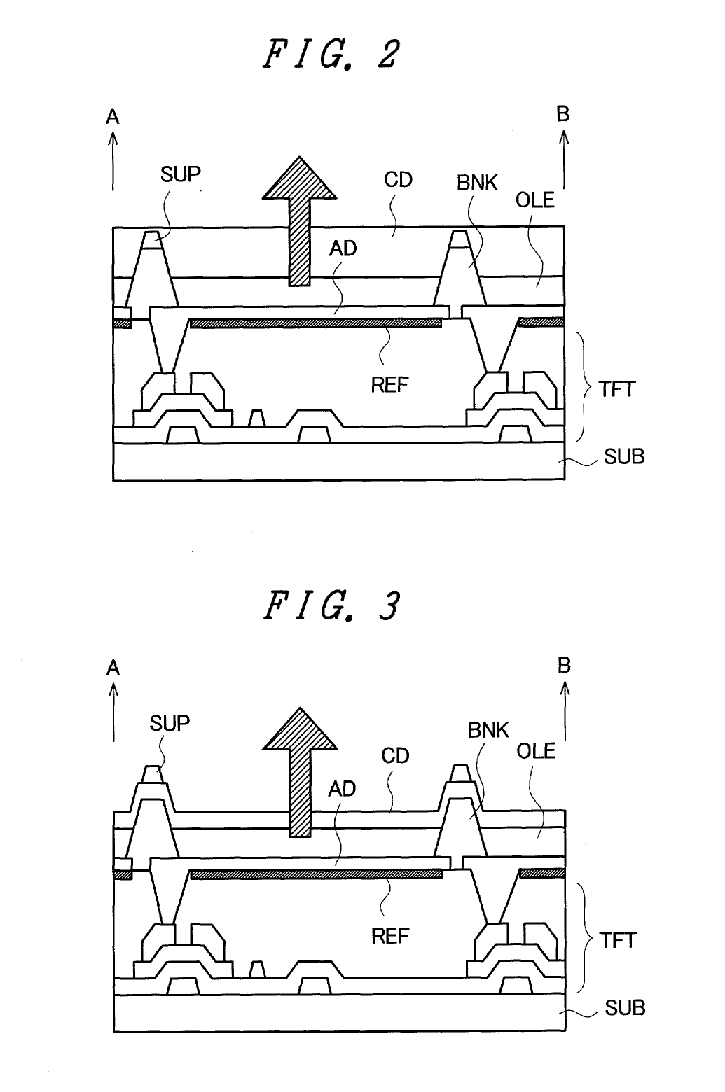

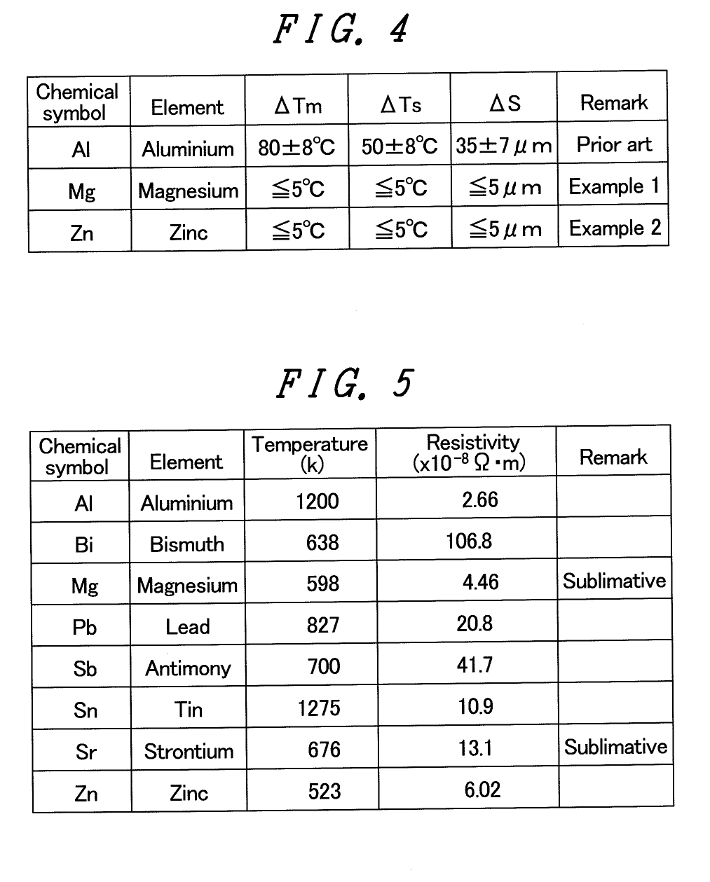

FIG. 2 is a cross-sectional view taken along a line A-B in FIG. 1. In FIG. 2, on a circuit layer including thin film transistors TFT, reflection films REF, the pixel electrodes AD, the pixel separation film BNK, an organic EL layer OLE, the auxiliary electrode SUP, and the common electrode CD are sequentially stacked in this order.

A channel of the thin film transistor TFT is formed of a semiconductor layer made of amorphous silicon to which crystallinity is imparted, wherein the reflection film REF is formed of a stacked film made of AlSi/MoW, the pixel electrode AD is made of ITO, the pixel separation film BNK is made of polyimide or SiN, the auxiliary electrode SUP is made of Mg or Zn, and the common electrode CD is made of IZO.

### (Manufacturing Process)

A stacked film made of AlSi/MoW is formed as the reflection film REF on a substrate SUB including the thin film transistors TFT by a sputtering method, and is patterned using a photolithography method. An ITO film is formed on the reflection film REF by a sputtering method, the pixel electrodes AD which are one-size larger than the reflection films are patterned using the photolithography method and, thereafter, the pixel electrodes AD are crystallized. The pixel separation film BNK is formed using polyimide or SiN so as to expose the centers of the pixel electrodes AD and to surround outer peripheries of the pixel electrodes AD. The organic EL layer OLE is formed on the pixel separation film BNK by a vapor deposition method. The auxiliary electrode SUP is formed on the organic EL layer OLE. The auxiliary electrode SUP is formed by an EB vapor deposition method (acceleration voltage: 10 kV), and the auxiliary electrode SUP is made of Mg or Zn. Here, a material of a vapor-deposition-use metal mask may be formed of a film made of 36Ni—Fe and having a thickness of 30 μm, and a gap between the metal mask and the substrate is set to 350 mm. Thereafter, the common electrode CD made of IZO is formed by a sputtering method.

### Embodiment 2

FIG. 1 is a partial top plan view of an effective display region of the organic EL display device to which the present invention is applied.

FIG. 3 is a partial cross-sectional view of the effective display region of the organic EL display device to which the present invention is applied.

### (Layer Structure)

FIG. 3 is a cross-sectional view taken along a line A-B in FIG. 1. In FIG. 3, on a circuit layer including thin film transistors TFT, reflection films REF, pixel electrodes AD, a pixel separation film BNK, an organic EL layer OLE, a common electrode CD, and an auxiliary electrode SUP are sequentially stacked in this order. A channel of the thin film transistor TFT is formed of a semiconductor layer made of amorphous silicon to which crystallinity is imparted, wherein the reflection film REF is formed of a stacked film made of AlSi/MoW, the pixel electrode AD is made of ITO, the pixel separation film BNK is made of polyimide or SiN, the common electrode CD is made of IZO, and the auxiliary electrode SUP is made of Mg or Zn. The constitution which makes this embodiment different from the embodiment 1 shown in FIG. 2 lies in that the auxiliary electrode is formed on the common electrode.

### (Manufacturing Process)

A stacked film made of AlSi/MoW is formed as the reflection film REF on a substrate SUB including the thin film transistors TFT by a sputtering method, and is patterned by a photolithography method. An ITO film is formed on the reflection films REF by a sputtering method, the pixel electrodes AD which are one-size larger than the reflection films are patterned by a photolithography method and, thereafter, the pixel electrodes AD are crystallized. The pixel separation film BNK is formed using polyimide or SiN so as to expose the centers of the pixel electrodes AD and to surround outer peripheries of the pixel electrodes AD. The organic EL layer OLE is formed on the pixel separation film BNK by a vapor deposition method. The common electrode CD is formed on the organic EL layer OLE by forming an IZO film on the whole display region by a sputtering method. Further, the auxiliary electrode SUP is formed on the common electrode CD. The auxiliary electrode SUP is formed by an EB vapor deposition method (acceleration voltage: 10 kV) by way of a metal mask, and the auxiliary electrode SUP is made of Mg or Zn. Here, a material of a vapor-deposition-use metal mask may be formed of a film made of 36Ni—Fe and having a thickness of 30 μm, and a gap between the metal mask and the substrate is set to 350 mm.

To recapitulate the above, as described in the respective embodiments, in the top-emission-type organic EL display device including the organic EL elements each of which is formed by stacking the pixel electrodes, the pixel separation film which surrounds the pixel electrodes, the organic EL layer and the common electrode, and forming a display screen on a common electrode side surface thereof, the auxiliary electrode which is brought into contact with an upper surface or a lower surface of the common electrode and has openings at positions where the auxiliary electrode overlap with the pixel electrodes is made of a material which contains Zn or Mg as a main component. Alternatively, an auxiliary electrode which is brought into contact with an upper surface or a lower surface of the common electrode and is arranged at positions where the auxiliary electrode overlaps with gaps between pixel electrodes is made of a material which contains Zn or Mg as a main component. By adopting either one of the above-mentioned constitutions, the auxiliary electrode can be formed by the low-temperature process. Accordingly, it is possible to reduce damages on the organic EL layer thus prolonging a lifetime of elements of the organic EL display device. The auxiliary electrode can be formed by any one of resistance-heating vapor deposition, induction-heating vapor deposition, EB vapor deposition and sputtering.

What is claimed is:

1. An organic EL display device including organic EL elements each of which is formed by sequentially stacking pixel electrodes, a pixel separation film which surrounds the pixel electrodes, an organic EL layer and a common electrode in this order, and forming a display screen on a common electrode side thereof, wherein
the organic EL display device includes an auxiliary electrode which is brought into contact with an upper surface or a lower surface of the common electrode and forms an opening at positions where the auxiliary electrode overlaps with the pixel electrodes, and
the auxiliary electrode is made of a material which contains Zn or Mg as a main component.

2. An organic EL display device according to claim 1, wherein sheet resistance which is the combined resistance of resistance of the common electrode and resistance of the auxiliary electrode is set to 10 Ωcm or less.

3. An organic EL display device according to claim 1, wherein the common electrode is made of metal oxide which contains In, Zn, or Sn.

4. An organic EL display device according to claim 1, wherein the auxiliary electrode is formed by any one of resistance-heating vapor deposition, induction-heating vapor deposition, EB vapor deposition and sputtering.

5. An organic EL display device including an organic EL element which is formed by stacking a plurality of pixel electrodes, an organic EL layer and a common electrode, and forms a display screen on a common electrode side, wherein
the organic EL display device includes an opaque auxiliary electrode which is brought into contact with an upper surface or a lower surface of the common electrode at positions where the auxiliary electrode overlaps with gaps formed between pixel electrodes, and
the auxiliary electrode is made of a material which contains Zn or Mg as a main component.

6. An organic EL display device according to claim 5, wherein seat resistance which is the combined resistance of resistance of the common electrode and resistance of the auxiliary electrode is set to 10 Ωcm or less.

7. An organic EL display device according to claim 5, wherein the common electrode is made of metal oxide which contains In, Zn, or Sn.

8. An organic EL display device according to claim 5, wherein the auxiliary electrode is formed by any one of resistance-heating vapor deposition, induction-heating vapor deposition, EB vapor deposition and sputtering.
